(19) United States
(12) Patent Application Publication
(10) Pub. No.: US 2025/0142787 A1
(43) Pub. Date: May 1, 2025

(54) LIQUID COOLING DISTRIBUTION DEVICE FOR DATA CENTER

(71) Applicant: Hebei Qinhuai Data Co., Limited., Zhangjiakou City (CN)

(72) Inventor: Binghua ZHANG, Zhangjiakou City (CN)

(21) Appl. No.: 18/900,822

(22) Filed: Sep. 29, 2024

(30) Foreign Application Priority Data
Nov. 1, 2023 (CN) 202311446560.5

(51) Int. Cl. H05K 7/20

(52) U.S. Cl. CPC H05K 7/20763

(57) ABSTRACT

The present disclosure discloses a liquid cooling distribution device for a data center, including a body, where a heat dissipation net is fixedly connected to the body, an interior of the body is provided with a filtering mechanism, a moving mechanism is arranged at a bottom of the body, a first liquid inlet is arranged at a top of the body, and a second liquid inlet is arranged at the top of the body. The filtering mechanism includes a mounting base, a filter stand, a filter net, a handle, a plug, a connecting rod, a pressing block, and a spring. The interior of the body is fixedly connected to the mounting base, an interior of the mounting base is slidably connected to the filter stand fixedly connected to the filter net, and an interior of the filter stand is slidably connected to the plug.

### CROSS REFERENCE TO RELATED APPLICATION

This application claims priority to Chinese Patent Application No. 202311446560.5, titled “LIQUID COOLING DISTRIBUTION DEVICE FOR DATA CENTER” and filed to the China National Intellectual Property Administration on Nov. 1, 2023, the entire contents of which are incorporated herein by reference.

### TECHNICAL FIELD

The present disclosure relates to the field of distribution device, and more particularly, to a liquid cooling distribution device for a data center.

### BACKGROUND

In the era of big data explosion, especially with the development of AI technologies, data volume is growing exponentially. Data centers for computation and storage of the data have also shown a development trend of high density and high power. One problem brought about by such development is heat dissipation. Conventional air cooling systems have gradually become overwhelmed, while liquid cooling technology has emerged due to its higher efficiency and lower energy consumption. For example, an invention patent with a patent authorization announcement number CN111328248A provides a fingerprint acquisition device, including an upper cover shell, a fingerprint acquisition board, an indicator light, a hanging ring, a bottom insulation board, a data port, a battery box, a suction cup, a coolant distribution device, and a liquid cooling cabinet. The coolant distribution device includes a liquid separation part, which is arranged at a bottom of a cabinet body of the liquid cooling cabinet and is communicated with a liquid inlet pipe of the liquid cooling cabinet. A surface of the liquid separation part is provided with a plurality of liquid separation holes along an arrangement direction of electronic equipment in the cabinet. In the liquid separation part, a main flow channel is arranged along the arrangement direction of the electronic equipment inside the cabinet, and a plurality of branches are arranged on one side or two sides of the main flow channel.

Existing liquid cooling distribution devices for data centers can improve uniformity of distribution of coolants, but the poured coolants are not filtered, and impurities in the coolants may block pipelines. Moreover, the devices are heavy and difficult to transport, making them time-consuming and laborious to move.

### SUMMARY

The present disclosure provides a liquid cooling distribution device for a data center, to prevent impurities in a poured coolant from blocking pipelines by filtering the coolant, thereby facilitating users to move the distribution device.

The liquid cooling distribution device for the data center provided by embodiments of the present disclosure includes a body. A heat dissipation net is fixedly connected to the body, an interior of the body is provided with a filtering mechanism, a moving mechanism is arranged at a bottom of the body, a first liquid inlet is arranged at a top of the body, and a second liquid inlet is arranged at the top of the body.

The filtering mechanism includes a mounting base, a filter stand, a filter net, a handle, a plug, a connecting rod, a pressing block, and a spring. The interior of the body is fixedly connected to the mounting base, and an interior of the mounting base is slidably connected to the filter stand, which is fixedly connected to the filter net. An interior of the filter stand is slidably connected to the plug, and the plug is fixedly connected to the connecting rod, which is slidably connected to the body.

The moving mechanism includes a motor, a rotation shaft, a first bevel gear, a second bevel gear, a threaded rod, a moving plate, and a moving wheel. An interior of the body is fixedly connected to the motor, and an output end of the motor is fixedly connected to the rotation shaft. The rotation shaft is fixedly connected to the first bevel gear, and the first bevel gear is meshed with the second bevel gear. An interior of the second bevel gear is fixedly connected to the threaded rod, the threaded rod is connected to the body through a bearing, and an outer side of the threaded rod is connected to the moving plate through a screw thread.

In the liquid cooling distribution device for the data center of the present disclosure, a box door is hinged on the body, and a handle groove is provided on the box door. Through the box door, it is convenient for maintenance personnel to open the body to maintain the device.

In the liquid cooling distribution device for the data center of the present disclosure, the pressing block is fixedly connected to the connecting rod, the pressing block is slidably connected to the body, and the interior of the body is provided with the spring.

In the liquid cooling distribution device for the data center of the present disclosure, the filter stand is fixedly connected to the handle, and a material of the handle is stainless steel. By using the handle, users can easily remove the filter stand to clean the filter net.

In the liquid cooling distribution device for the data center of the present disclosure, one end of the spring is fixedly connected to the connecting rod, and other end of the spring is fixedly connected to the body. By means of elastic force of the spring itself, the connecting rod is pushed to drive the plug to insert into the filter stand, making it easier to fix the filter stand.

In the liquid cooling distribution device for the data center of the present disclosure, the moving plate is slidably connected to the body, and a moving wheel is provided on the moving plate. By means of the moving mechanism, it is convenient for the users to lower the moving wheel during transportation, making it easier for the users to move the device.

The technical solutions provided in the embodiments of the present disclosure may include the following beneficial effects. In the present disclosure, a liquid cooling distribution device for a data center is designed. By designing the filtering mechanism, it is easy to filter a poured coolant and prevent impurities in the coolant from blocking pipelines. Furthermore, the filter stand may be removed to facilitate cleaning of the filter net and to maintain filtering efficiency.

The present disclosure designs the liquid cooling distribution device for the data center. By means of the moving mechanism arranged on the body, users can control the moving wheel to lift through the motor, thereby facilitating transportation of the distribution device. When the distribution device is transported to a desired position, the moving wheel may also be retracted into the body, allowing a bottom of the body to touch the ground, increasing a contact area between the bottom of the body and the ground, and thus ensuring the device to be placed more stably.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a three-dimensional view of an overall structure according to Embodiment I of the present disclosure;

FIG. 2 is a partial elevation view of a body structure in FIG. 1; and

FIG. 3 is a partial vertical view of the body structure in FIG. 1.

Reference numerals in the accompanying drawings:

body 1; box door 2; handle groove 3; heat dissipation net; filtering mechanism 4; mounting base 51; filter stand 52; filter net 53; handle 54; plug 55; connecting rod 56; pressing block 57; spring 58; moving mechanism 6; motor 61; rotation shaft 62; first bevel gear 63; second bevel gear 64; threaded rod 65; moving board 66; moving wheel 67; first liquid inlet 7; and second liquid inlet 8.

### DETAILED DESCRIPTION

Technical solutions in the embodiments of the present disclosure will be described clearly and completely below, in conjunction with the accompanying drawings in the embodiments of the present disclosure. Apparently, the described embodiments are some but not all of the embodiments of the present disclosure. All other embodiments obtained by a person of ordinary skill in the art based on the embodiments of the present disclosure without creative efforts shall fall within the protection scope of the present disclosure.

It should also be understood that the terms used in this specification of the present disclosure are only for the purpose of describing particular embodiments and are not intended to limit the present disclosure. As used in the specification and the appended claims of the present disclosure, the singular forms of “a”, “an” and “the” may be intended to include the plural forms, unless the context clearly indicates otherwise.

It should also be further understood that the term “and/or” used in the specification and the appended claims of the present disclosure refers to any combination of one or more of the relevantly listed items and all possible combinations, and includes these combinations.

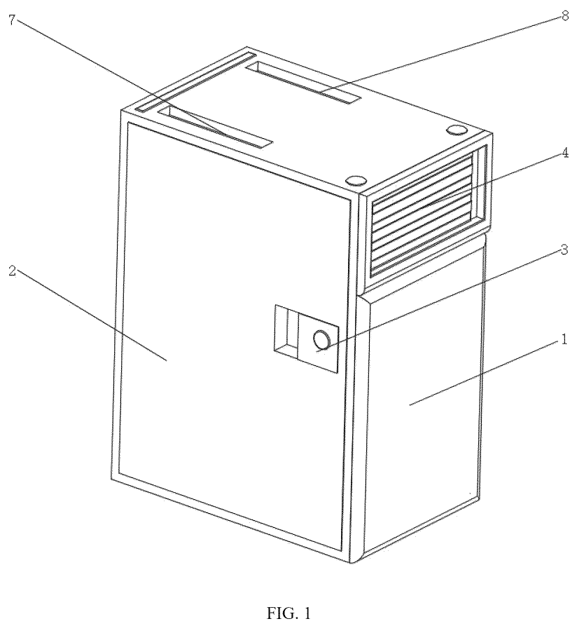

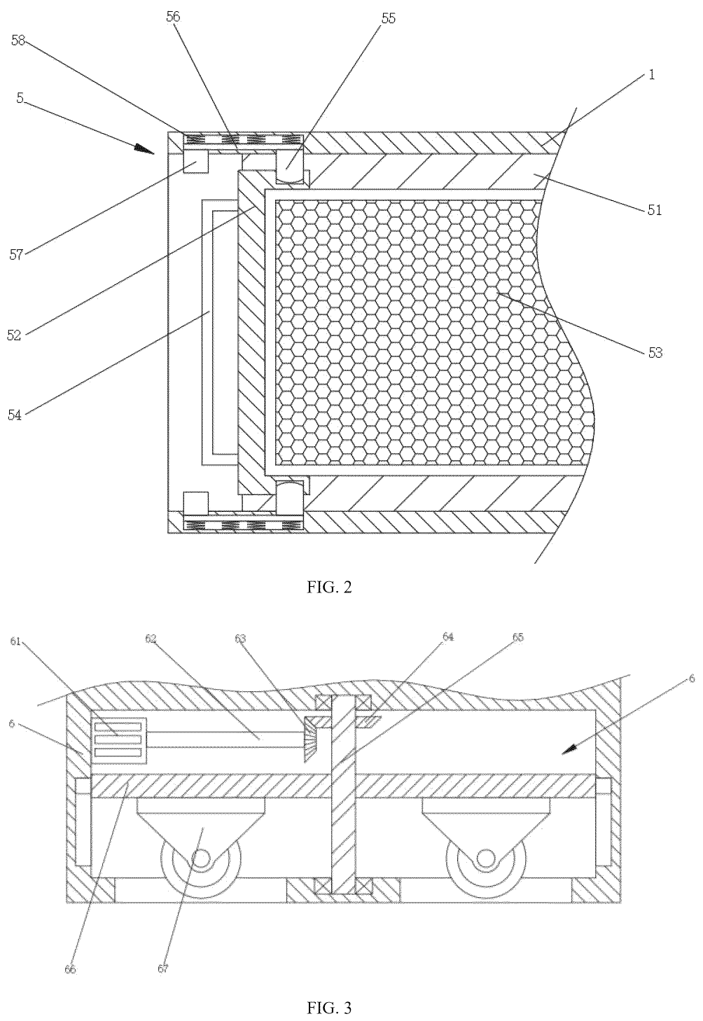

Referring to FIG. 1, FIG. 2, and FIG. 3, the present disclosure discloses a liquid cooling distribution device for a data center, which includes a body 1. A box door 2 is hinged on the body 1, and a handle groove 3 is provided on the box door 2. By means of the box door 2 hinged on the body 1, it is convenient for operation personnel to open the box door 2 to maintain the distribution device. A heat dissipation net 4 is fixedly connected to the body 1, and an interior of the body 1 is provided with a filtering mechanism 5. By means of the filtering mechanism 5, it is easy to filter a poured coolant and thus prevent impurities in the coolant from blocking pipelines. A moving mechanism 6 is arranged at a bottom of the body 1, a first liquid inlet 7 is arranged at a top of the body 1, and a second liquid inlet 8 is arranged at the top of the body 1. The first liquid inlet 7 and the second liquid inlet 8 are used for a liquid to enter the body 1.

Referring to FIG. 1 and FIG. 2, the filtering mechanism 5 includes a mounting base 51, a filter stand 52, a filter net 53, a handle 54, a plug 55, a connecting rod 56, a pressing block 57, and a spring 58. The interior of the body 1 is fixedly connected to the mounting base 51, and an interior of the mounting base 51 is slidably connected to the filter stand 52. The filter stand 52 is fixedly connected to the filter net 53, and the filter stand 52 is fixedly connected to the handle 54. By means of the handle 54, it is convenient for a user to take out the filter stand 52 to facilitate cleaning of the filter net 53. An interior of the filter stand 52 is slidably connected to the plug 55, the plug 55 is fixedly connected to the connecting rod 56, and the connecting rod 56 is slidably connected to the body 1. The pressing block 57 is fixedly connected to the connecting rod 56, the pressing block 57 is slidably connected to the body 1, and the interior of the body 1 is provided with the spring 58. By means of elastic force of the spring 58, the connecting rod 56 is pushed to drive the plug 55 to insert into the filter stand 52, making it easier to fix the filter stand 52. One end of the spring 58 is fixedly connected to the connecting rod 56, and other end of the spring 58 is fixedly connected to the body 1. By means of the filtering mechanism 5, the poured coolant may be filtered to prevent the impurities in the coolant from blocking the pipelines.

Referring to FIG. 1 and FIG. 3, the moving mechanism 6 includes a motor 61, a rotation shaft 62, a first bevel gear 63, a second bevel gear 64, a threaded rod 65, a moving plate 66, and a moving wheel 67. The interior of the body 1 is fixedly connected to the motor 61, and an output end of the motor 61 is fixedly connected to the rotation shaft 62. The rotation shaft 62 is fixedly connected to the first bevel gear 63, and the first bevel gear 63 is meshed with the second bevel gear 64. An interior of the second bevel gear 64 is fixedly connected to the threaded rod 65, and the threaded rod 65 is connected to the body 1 through a bearing. An outer side of the threaded rod 65 is connected to the moving plate 66 through a screw thread. The moving plate 66 is slidably connected to the body 1, and the moving wheel 67 is provided on the moving plate 66. By means of the moving mechanism 6, it is convenient for the user to lower the moving wheel 67 during transportation, to facilitate the user to move the device.

Specific implementation processes of the present disclosure are as follows. By means of the filtering mechanism 5, the poured coolant may be filtered to prevent the impurities in the coolant from blocking the pipelines. When the filter net 53 filters too much impurities, the pressing blocks 57 on two sides may be pressed down, allowing the pressing blocks 57 to drive the connecting rod 56 to move while the spring 58 is compressed, such that the connecting rod 56 drives the plug 55 to detach from the filter stand 52. By using the handle 54, the user can easily take out the filter stand 52 to clean the filter net 53, thereby maintaining filtering efficiency of the filter net 53. After the cleaning, the filter stand 52 is inserted back into the mounting base 51, and the pressing blocks 57 are released. Under the elastic force of the spring 58, the spring 58 may push the connecting rod 56, such that the connecting rod 56 drives the plug 55 to insert into the filter stand 52. In this way, fixing of the filter stand 52 is completed. When it is required to move the distribution device, the motor 61 is started to drive the rotation shaft 62 on the output end of the motor 61 to rotate, such that the rotation shaft 62 drives the second bevel gear 64 hinged to the first bevel gear 63 to rotate, which causes the threaded rod 65 to carry out threaded motion with respect to the moving plate 66, causing the moving plate 66 to drive the moving wheel 67 to move and thus the moving wheel 67 is lowered, making it easier for the user to move the device. After the device is moved, the motor 61 is started to inversely rotate and retract the moving plate 66, which allows a bottom of the body 1 to touch the ground, increasing a contact area between the bottom of the body 1 and the ground, and thus ensuring the device to be placed more stably.

The preceding descriptions are merely specific embodiments of the present disclosure, but the protection scope of the present disclosure is not limited thereto. Any equivalent modifications or replacements easily conceivable to a person of skilled in the art within the technical scope disclosed in the present disclosure shall fall within the protection scope of the present disclosure. Therefore, the protection scope of the present disclosure shall be subject to that of the claims.

What is claimed is:

1. A liquid cooling distribution device for a data center comprising a body, wherein a heat dissipation net is fixedly connected to the body, an interior of the body is provided with a filtering mechanism, a moving mechanism is arranged at a bottom of the body, a first liquid inlet is arranged at a top of the body, and a second liquid inlet is arranged at the top of the body;
the filtering mechanism comprises a mounting base, a filter stand, a filter net, a handle, a plug, a connecting rod, a pressing block, and a spring; the interior of the body is fixedly connected to the mounting base, an interior of the mounting base is slidably connected to the filter stand, the filter stand is fixedly connected to the filter net, an interior of the filter stand is slidably connected to the plug, the plug is fixedly connected to the connecting rod, and the connecting rod is slidably connected to the body; and
the moving mechanism comprises a motor, a rotation shaft, a first bevel gear, a second bevel gear, a threaded rod, a moving plate, and a moving wheel; an interior of the body is fixedly connected to the motor, an output end of the motor is fixedly connected to the rotation shaft, the rotation shaft is fixedly connected to the first bevel gear, the first bevel gear is meshed with the second bevel gear, an interior of the second bevel gear is fixedly connected to the threaded rod, the threaded rod is connected to the body through a bearing, and an outer side of the threaded rod is connected to the moving plate through a screw thread.

2. The liquid cooling distribution device for the data center according to claim 1, wherein a box door is hinged on the body, and a handle groove is provided on the box door.

3. The liquid cooling distribution device for the data center according to claim 1, wherein the pressing block is fixedly connected to the connecting rod, the pressing block is slidably connected to the body, and the interior of the body is provided with the spring.

4. The liquid cooling distribution device for the data center according to claim 1, wherein the filter stand is fixedly connected to the handle, and a material of the handle is stainless steel.

5. The liquid cooling distribution device for the data center according to claim 1, wherein one end of the spring is fixedly connected to the connecting rod, and other end of the spring is fixedly connected to the body.

6. The liquid cooling distribution device for the data center according to claim 1, wherein the moving plate is slidably connected to the body, and a moving wheel is provided on the moving plate.
